(19) United States
(12) Patent Application Publication
(10) Pub. No.: US 2023/0386872 A1
(43) Pub. Date: Nov. 30, 2023

(54) TRANSPORT CONTROL APPARATUS AND LOGISTICS TRANSPORT SYSTEM INCLUDING THE SAME

(71) Applicant: SEMES CO., LTD., Cheonan-si (KR)

(72) Inventor: Da Hye JUNG, Cheonan-si (KR)

(73) Assignee: SEMES CO., LTD., Cheonan-si (KR)

(21) Appl. No.: 18/322,210

(22) Filed: May 23, 2023

(30) Foreign Application Priority Data
May 26, 2022 (KR) 10-2022-0064543

(51) Int. Cl. H01L 21/67; G06Q 50/30; G06Q 50/28

(52) U.S. Cl. CPC H01L 21/67276; G06Q 50/30; G06Q 50/28

(57) ABSTRACT

Provided is a transport control device for integrating and controlling different types of transport means and a logistics transport system including the same. The logistics transport system comprises a plurality of first transport devices disposed in a semiconductor manufacturing plant and for transporting a transported object; a plurality of second transport devices different in type from the plurality of first transport devices; and a transport control device for controlling the plurality of first transport devices and the plurality of second transport devices, wherein the transport control device integrates and operates different types of transport devices to transport the transported object.

This application claims the benefit of Korean Patent Application No. 10-2022-0064543, filed on May 26, 2022, in the Korean Intellectual Property Office, the disclosure of which is incorporated herein by reference in its entirety.

### BACKGROUND

### 1. Field

The present disclosure relates to a transport control device and a logistics transport system including the same. More specifically, it relates to a transport control device for controlling a device for transporting containers in a semiconductor manufacturing plant and a logistics transport system including the same.

### 2. Description of the Related Art

Wafers used to produce semiconductors may undergo various processes in a semiconductor manufacturing plant (e.g., FAB), and may be transported to respective process facilities for this purpose. For example, a plurality of wafers are accommodated in a container such as a front opening unified pod (FOUP), and each of the containers may be transported to a process facility through a transport vehicle such as an overhead hoist transport (OHT) movably provided on the ceiling of a semiconductor manufacturing plant.

### SUMMARY

In order to shorten the time required to produce semiconductors, OHTs as well as Automated Guided Vehicles (AGVs) are being utilized for transporting transported objects (e.g., containers). The AGV is a transport vehicle that is prepared to travel on the ground within a semiconductor manufacturing plant, and can also contribute to automating and unmanning a semiconductor manufacturing plant along with OHT.

However, conventional control systems for operating OHT and AGV, such as OCS (OHT Control System) and ACS (AGV Control System), expose problems in the following aspects.

First, the conventional control system is capable of controlling only one type of transport means. That is, the control system is separately operated for each transport means. Accordingly, the upper transport system should deliver transport suitable for the characteristics of each transport means to each control system when transport is generated. In addition, when it is possible to transport one transported object by two or more transport means, the upper transport system should determine the position of the transported object, specify the transport means, and assign the transport to the control system that controls the corresponding transport means.

Second, after assigning one task to a specific transport means, the control system that controls the specific transport means periodically searches for an optimal path for the transport means (Dynamic Path Search). In this case, it is possible to search only the path for the transport means initially assigned, and after unloading or picking up the transported object, it is possible to search only for the transport path for the corresponding means. For example, if congestion occurs while transporting a transported object through OHT, the OHT waits on a rail, and proceeds with transporting the transported object only when the congestion is resolved.

A technical problem to be solved by the present disclosure is to provide a transport control device for integrating and controlling different types of transport means and a logistics transport system including the same.

The technical problems of the present disclosure are not limited to the technical problems mentioned above, and other technical problems not mentioned will be clearly understood by those skilled in the art from the following description.

One aspect of the logistics transport system of the present disclosure for achieving the above technical problem comprises a plurality of first transport devices disposed in a semiconductor manufacturing plant and for transporting a transported object; a plurality of second transport devices different in type from the plurality of first transport devices; and a transport control device for controlling the plurality of first transport devices and the plurality of second transport devices, wherein the transport control device integrates and operates different types of transport devices to transport the transported object.

The transport control device transports the transported object using any one of the first transport device and the second transport device, and transports the transported object using another one when a failure occurs.

The transport control device dynamically assigns transport of the transported object to the different types of transport devices.

The transport control device avoids an unmovable section or shortens a moving section by using the different types of transport devices.

The transport control device searches for an optimal path in real time for a plurality of transport devices including a transport device transporting the transported object while the transported object is being transported.

The transport control device selects a transport device to transport the transported object based on a transport cost. The transport cost is calculated based on at least one of a moving distance, a moving time, and idleness.

The transport control device monitors in real time whether it is possible to reduce a transport cost in relation to transport of the transported object when a specific transport device transports the transported object. The transport control device considers a transport path or a transport target when monitoring whether it is possible to reduce the transport cost. The transport control device sequentially considers the transport path and the transport target.

The transport control device modifies a transport path or replaces a transport device according to a transport cost when a specific transport device transports the transported object. The transport control device compares an existing path with a new path and modifies a transport path to the new path if the new path is an optimal path considering the transport cost. The transport control device compares the specific transport device with other transport device and replaces the transport device with the other transport device when the other transport device has an optimal path, in which the transport cost is considered.

The plurality of first transport devices travel on a ceiling of the semiconductor manufacturing plant to transport the transported object, and the plurality of second transport devices travel on a ground of the semiconductor manufacturing plant to transport the transported object.

The logistics transport system further comprises a plurality of third transport devices different in type from the plurality of first transport devices and the plurality of second transport devices.

In addition, another aspect of the logistics transport system of the present disclosure for achieving the above technical problem comprises a plurality of first transport devices disposed in a semiconductor manufacturing plant and for transporting a transported object; a plurality of second transport devices different in type from the plurality of first transport devices; and a transport control device for controlling the plurality of first transport devices and the plurality of second transport devices, wherein the transport control device transports the transported object by integrating and operating different types of transport devices, wherein the transport control device dynamically assigns transport of the transported object to the different types of transport devices, wherein the transport control device avoids an unmovable section or shortens a moving section by using the different types of transport devices, wherein the transport control device monitors in real time whether it is possible to reduce a transport cost in relation to transport of the transported object when a specific transport device transports the transported object, wherein the transport control device modifies a transport path or replaces the transport device according to the transport cost when the specific transport device transports the transported object.

In addition, one aspect of the transport control device of the present disclosure for achieving the above technical problem is a transport control device disposed in a semiconductor manufacturing plant, wherein the transport control device controls a plurality of first transport devices for transporting a transported object and a plurality of second transport devices different in type from the plurality of first transport devices, transports the transported object by integrating and operating different types of transport devices, and dynamically assigns transport of the transported object to the different type of transport devices.

Details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a first block diagram schematically showing the internal configuration of a logistics transport system including various types of transport devices;

FIG. 2 is a diagram showing the structure of the first transport device constituting the logistics transport system by way of example;

FIG. 3 is a diagram showing an installation shape of a first transport device in a semiconductor manufacturing plant by way of example;

FIG. 4 is a second block diagram schematically showing the internal configuration of a logistics transport system including various types of transport devices;

FIG. 5 is an exemplary diagram for describing a method for a transport control device constituting a logistics transport system to control different types of transport devices;

FIG. 6 is a first exemplary diagram for describing dynamic assignment and integrated control of a transport control device constituting a logistics transport system;

FIG. 7 is a second exemplary diagram for describing dynamic assignment and integrated control of a transport control device constituting a logistics transport system;

FIG. 8 is a third exemplary diagram for describing dynamic assignment and integrated control of a transport control device constituting a logistics transport system;

FIG. 9 is a first exemplary diagram for describing path search and task assignment for each transport means of the transport control device constituting the logistics transport system;

FIG. 10 is a second exemplary diagram for describing path search and task assignment for each transport means of the transport control device constituting the logistics transport system; and

FIG. 11 is a third exemplary diagram for describing path search and task assignment for each transport means of the transport control device constituting the logistics transport system.

### DETAILED DESCRIPTION

Hereinafter, embodiments of the present disclosure will be described in detail with reference to the accompanying drawings. The same reference numerals are used for the same components in the drawings, and duplicate descriptions thereof are omitted.

The present disclosure relates to a transport control device that integrates and controls different types of transport means and a logistics transport system including the same when various types of transport means (for example, OHT (Overhead Hoist Transport), AGV (Automated Guided Vehicle), etc.) transport transported objects in a semiconductor manufacturing plant. Hereinafter, the present disclosure will be described in detail with reference to the drawings and the like.

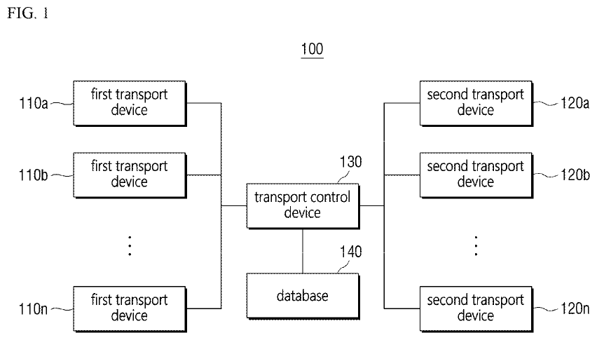

FIG. 1 is a first block diagram schematically showing the internal configuration of a logistics transport system including various types of transport devices.

According to FIG. 1, the logistics transport system 100 may comprise a plurality of first transport devices 110a, 110b, . . . , 110n, a plurality of second transport devices 120a, 120b, . . . , 120n, a transport control device 130, and a database 140. The logistics transport system 100 may be applied to providing a logistics automation service in a semiconductor manufacturing plant.

The plurality of first transport devices 110a, 110b, . . . , 110n play a role of transporting the transported object to the destination. In the semiconductor manufacturing plant, a plurality of first transport devices 110a, 110b, . . . , 110n may be provided to play the above role, but the present embodiment is not limited thereto, and it is also possible that single first transport device 110a is provided. The plurality of first transport devices 110a, 110b, . . . , 110n may be provided as, for example, OHT.

The plurality of first transport devices 110a, 110b, . . . , 110n may transport the transported object to a destination by traveling along a moving path (e.g., a rail) installed on the ceiling of a semiconductor manufacturing plant. The plurality of first transport devices 110a, 110b, . . . , 110n may transport a transported object to various process facilities, in which semiconductor manufacturing processes are performed (e.g., a deposition process chamber, an etching process chamber, a cleaning process chamber, a heating/cooling process chamber, etc.).

When the plurality of first transport devices 110a, 110b, . . . , 110n transport the transported objects to facilities where semiconductor manufacturing processes are performed, the transported objects may be containers, in which a plurality of substrates (e.g., wafers) are accommodated. The container may be prepared as, for example, a Front Opening Unified Pod (FOUP). However, the transported objects are not limited thereto, and the transported objects in this embodiment can be understood as a concept encompassing all objects to be transported in a semiconductor manufacturing plant.

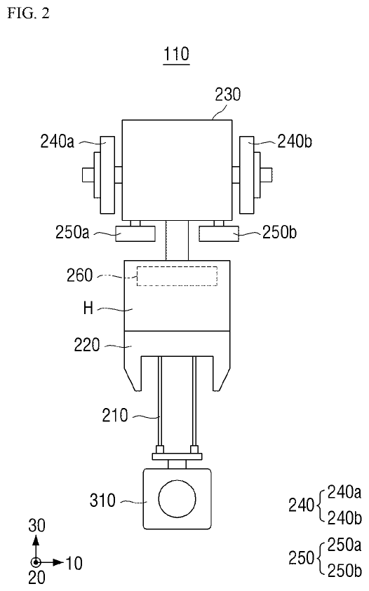

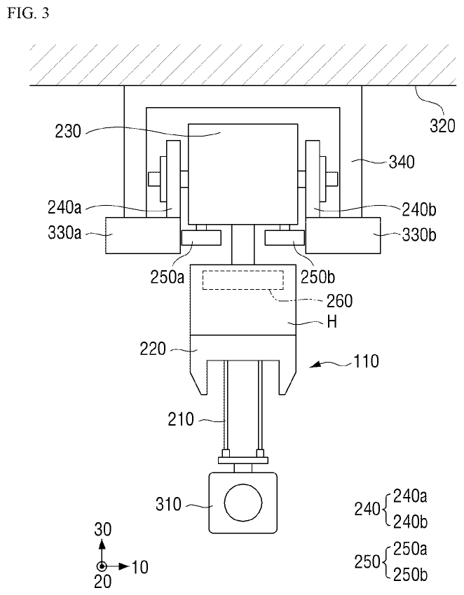

The plurality of first transport devices 110a, 110b, . . . , 110n may operate under the control of the transport control device 130. Although not shown in FIGS. 2 and 3, the plurality of first transport devices 110a, 110b, . . . , 110n may include a communication module for wired/wireless communication with the transport control device 130 for this purpose.

The plurality of first transport devices 110a, 110b, . . . , 110n may operate autonomously without being controlled by the transport control device 130. In this case, a plurality of sensors for providing information may be installed around the moving path so that the plurality of first transport devices 110a, 110b, . . . , 110n disposed in the semiconductor manufacturing plant do not collide with each other, and a plurality of first transport devices 110a, 110b, . . . , 110n may be provided so that they can communicate with each other.

FIG. 2 is a diagram showing the structure of the first transport device constituting the logistics transport system by way of example, and FIG. 3 is a diagram showing the installation shape of the first transport device in a semiconductor manufacturing plant by way of example.

Hereinafter, with reference to FIGS. 2 and 3, when the 1A transport device 110a, which is any one of the plurality of first transport devices 110a, 110b, . . . , 110n, is a device that transports the container 310, its structure and the installation shape will be described, but in this embodiment, 1B transport device 110b, . . . , 1N transport device 110n other than the 1A transport device 110a also have the same structure and installation shape as the 1A transport device 110a.

According to FIGS. 2 and 3, the 1A transport device 110a may comprise a gripping module 210, an elevating module 220, a driving module 230, a driving wheel 240, a guide wheel 250 and a control module 260.

The gripping module 210 is provided to grip the container 310. The gripping module 210 may descend to a place where the container 310 is placed (e.g., an Equipment Front End Module (EFEM)) and grip the container 310 in order to transport the container 310 to a destination. The gripping module 210 may be provided as, for example, a hand gripper.

The elevating module 220 is provided to elevate the gripping module 210. The elevating module 220 may lower the gripping module 210 from the vicinity of the ceiling 320 to the direction where the ground is located so that the gripping module 210 can grip the container 310, and may raise the gripping module 210 again near the ceiling 320 when the gripping module 210 grips the container 310. The elevating module 220 may be provided as, for example, a hoist.

When the container 310 is loaded by the gripping module 210 and the elevating module 220 in this way, the 1A transport device 110a can transport the container 310 to the destination in this state. When the 1A transport device 110a reaches the destination, the elevating module 220 lowers the gripping module 210 again, and the gripping module 210 releases the gripping of a container 310 seated on the load port module of the EFEM to transfer the plurality of substrates accommodated in the container 310 to a process facility where a next semiconductor manufacturing process is performed.

Meanwhile, although not shown in FIGS. 2 and 3, the 1A transport device 110a may comprise a storage module providing a storage space instead of the gripping module 210. The storage module may be formed in a shape with an open top (e.g., basket type) to accommodate the container 310, and may be formed in a shape, in which an openable door is installed on the side, (e.g., cabinet type).

The driving module 230 serves to control the driving wheels 240 traveling along a moving path (e.g., a pair of rails 330a and 330b) installed on the ceiling 320 of a semiconductor manufacturing plant. Although not shown in FIGS. 2 and 3, the driving module 230 may include a driving motor and a driving shaft for this purpose. Here, the driving motor may serve to generate driving force, and the driving shaft may serve to provide the driving force generated by the driving motor to the driving wheel 240.

The driving wheel 240 is a rotating body that rotates using the driving force provided by the driving module 230, and through such rotation, the 1A transport device 110a can travel on the pair of rails 330a and 330b. The driving wheels 240 may be provided as a pair 240a, 240b so as to travel on the rails 330a and 330b on each side. In this case, the pair of driving wheels 240a and 240b may be coupled to both sides of the driving module 230, respectively.

When the 1A transport device 110a travels on the pair of rails 330a and 330b, the guide wheel 250 serves to prevent the 1A transport device 110a from being separated from the rails 330a and 330b. The guide wheels 250 may be provided as a pair 250a, 250b like the driving wheels 240, and may be installed at both ends of the lower surface of the driving module 230 so as to be perpendicular to the driving wheels 240a, 240b.

The control module 260 serves to control each module constituting the 1A transport device 110a. For example, the control module 260 serves to control the operation of the gripping module 210 and the elevating module 220, and may serve to control the operation of a driving motor constituting the driving module 230. In addition, although not shown in FIGS. 2 and 3, the control module 260 has a front frame and a rear frame on its front and rear surfaces, respectively, and may also serve to support the gripping module 210 and the elevating module 220 coupled to its lower surface. The control module 260 may be provided as, for example, an OHT controller.

Although not shown in FIGS. 2 and 3, the control module 260 may include a speed adjusting unit and a position adjusting unit. Here, the speed adjusting unit may serve to control the rotational speed of the driving wheel 240 and the position adjusting unit may serve to correct the position of the container 310.

The position adjusting unit may include a slider and a rotator. The slider may serve to move the container 310 up and down or left and right, and the rotator may serve to rotate the container 310 clockwise or counterclockwise.

A rail assembly including a pair of rails 330a and 330b and a rail support module 340 may be installed on the ceiling 320 of the semiconductor manufacturing plant in order to provide a moving path to the 1A transport device 110a. As described above, the pair of rails 330a and 330b provide a travel path to the 1A transport device 110a, and may be coupled to both ends of the rail support module 340 fixed to the ceiling 320 of the semiconductor manufacturing plant.

The pair of rails 330a and 330b may be configured to include various types of sections such as a straight section, a curved section, an inclined section, a branching section, and an intersection section according to the layout of the ceiling 320 in the semiconductor manufacturing plant. However, the present embodiment is not limited thereto. The pair of rails 330a and 330b may also be configured to include only one type of section among the plurality of sections.

The rail support module 340 is fixed to the ceiling 320 of a semiconductor manufacturing plant and serves to support a pair of rails 330a and 330b. The rail support module 340 may be installed on the ceiling 320 of a semiconductor manufacturing plant to have a cap shape when viewed from the ground.

It will be described with reference to FIG. 1 again.

Like the plurality of first transport devices 110a, 110b, . . . , 110n, the plurality of second transport devices 120a, 120b, . . . , 120n serve to transport the transported object to the destination. In the semiconductor manufacturing plant, the plurality of second transport devices 120a, 120b, . . . , 120n may be provided to play the above role, but the present embodiment is not limited thereto, and it is also possible that single second transport device 120a is provided. The plurality of second transport devices 120a, 120b, . . . , 120n are transport devices of a different type from the plurality of first transport devices 110a, 110b, . . . , 110n, and may be provided as, for example, AGV or AMR (Autonomous Mobile Robot).

The plurality of second transport devices 120a, 120b, . . . , 120n may travel on the ground of the semiconductor manufacturing plant and transport the transported object to a destination. The plurality of second transport devices 120a, 120b, . . . , 120n may transport the transported object to a process facility where a semiconductor manufacturing process is performed (e.g., a test process chamber such as a burn-in chamber).

The plurality of second transport devices 120a, 120b, . . . , 120n may operate under the control of the transport control device 130. Although not shown in FIGS. 2 and 3, the plurality of second transport devices 120a, 120b, . . . , 120n may include a communication module for wired/wireless communication with the transport control device 130 for this purpose.

The plurality of second transport devices 120a, 120b, . . . , 120n may operate autonomously without being controlled by the transport control device 130. In this case, a plurality of sensors for providing information may be distributed on the ground so that the plurality of second transport devices 120a, 120b, . . . , 120n disposed in the semiconductor manufacturing plant do not collide with each other, and the plurality of second transport devices 120a, 120b, . . . , 120n may be provided so that they can communicate with each other.

The transport control device 130 serves to control the plurality of first transport devices 110a, 110b, . . . , 110n and the plurality of second transport devices 120a, 120b, . . . , 120n. The transport control device 130 may independently control each of the first transport devices 110a, 110b, . . . , 110n and each of the second transport devices 120a, 120b, . . . , 120n so that each of the first transport devices 110a, 110b, . . . , 110n and each of the second transport devices 120a, 120b, . . . , 120n can safely transport the transported object to a destination (e.g., various process facilities where a semiconductor manufacturing process is performed).

The transport control device 130 may send a start command, a stop command, an acceleration command, and a deceleration command to the plurality of first transport devices 110a, 110b, . . . , 110n and the plurality of second transport devices 120a, 120b, . . . , 120n to control the travel of the plurality of first transport devices 110a, 110b, . . . , 110n and the plurality of second transport devices 120a, 120b, . . . , 120n. In addition, the transport control device 130 may provide information necessary to a plurality of first transport device 110a, 110b, . . . , 110n and a plurality of second transport devices 120a, 120b, . . . , 120n (for example, a path to a destination) through wired/wireless communication with the plurality of first transport devices 110a, 110b, . . . , and 110n and the plurality of second transport devices 120a, 120b, . . . , and 120n.

The transport control device 130 may recognize the positions of the plurality of first transport devices 110a, 110b, . . . , 110n and the plurality of second transport devices 120a, 120b, . . . , 120n in order to play the above role. In this case, the transport control device 130 may use a plurality of sensors installed around the moving path of the plurality of first transport devices 110a, 110b, . . . , 110n and the plurality of second transport devices 120a, 120b, . . . , 120n, and also may use results obtained by wired/wireless communication with the plurality of first transport devices 110a, 110b, . . . , 110n and the plurality of second transport devices 120a, 120b, . . . , 120n.

In the above, in the former case, the transport control device 130 may recognize the positions of the plurality of first transport devices 110a, 110b, . . . , 110n and the plurality of second transport devices by using identification information (e.g., serial number) of the corresponding sensor, position information (e.g., two-dimensional coordinate information (x, y) or three-dimensional coordinate information (x, y, z)) of the corresponding sensor, and identification information of the container transport device that has passed through the corresponding sensor. On the other hand, in the latter case, the plurality of first transport devices 110a, 110b, . . . , 110n and the plurality of second transport devices 120a, 120b, . . . , 120n can measure their own positions, and the transport control device 130 can recognize the positions of the plurality of first transport devices 110a, 110b, . . . , 110n and the plurality of second transport devices 120a, 120b, . . . , 120n through communication with the corresponding container transport device.

The transport control device 130 may be provided as a computer or server by including a process controller, a control program, an input module, an output module (or display module), a memory module, and the like to control the plurality of first transport devices 110a, 110b, . . . , 110n and the plurality of second transport devices 120a, 120b, . . . , 120n. Here, the process controller may include a microprocessor that executes a control function for each component constituting the logistics transport system 100, and the control program may execute various processes in the logistics transport system 100 under the control of the process controller. The memory module may store programs for executing various processes in the logistics transport system 100 according to various data and processing conditions, that is, processing recipes.

The database 140 serves to store information necessary for the transport control device 130 to control the plurality of first transport devices 110a, 110b, . . . , 110n and the plurality of second transport devices 120a, 120b, . . . , 120n. The database 140 may be installed inside the transport control device 130 or may be provided separately outside the transport control device 130 and connected by wire/wireless connection to provide information required by the transport control device 130.

The logistics transport system 100 described above with reference to FIGS. 1 to 3 includes different types of first transport devices 110a, 110b, . . . , 110n and second transport devices 120a, 120b, . . . , 120n. The first transport devices 110a, 110b, . . . , 110n are, for example, OHTs, and the second transport devices 120a, 120b, . . . , 120n are, for example, AGVs. However, the logistics transport system 100 is not limited thereto, and may further include another type of transport device. For example, the logistics transport system 100 may comprise a plurality of first transport devices 110, a plurality of second transport devices 120, . . . , a plurality of nth transport devices 150, a transport control device 130, and a database 140.

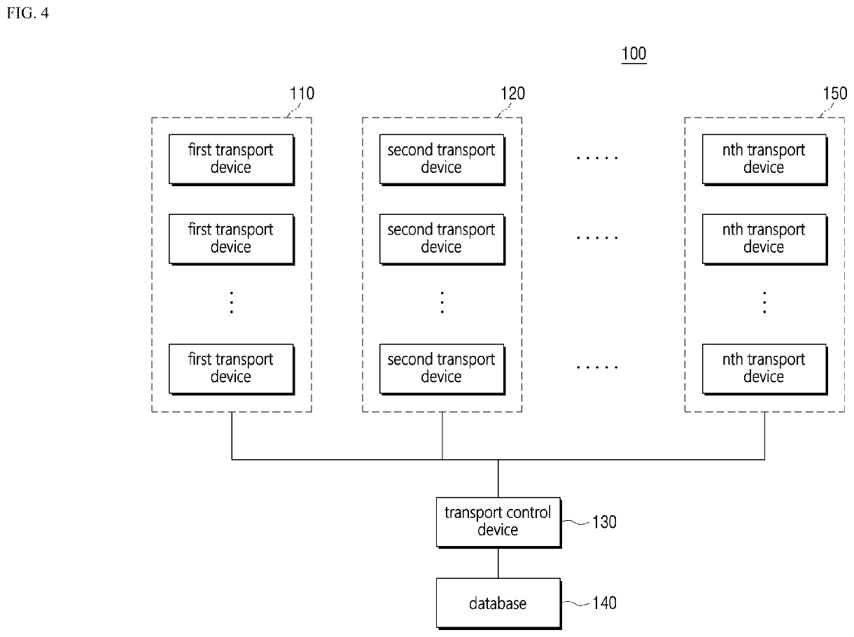

In the above, the plurality of nth transport devices 150 is a transport device of a different type from the plurality of first transport devices 110 and the plurality of second transport devices 120, and may be provided as, for example, a tower lifter serving as an interlayer transporter. FIG. 4 is a second block diagram schematically showing the internal configuration of a logistics transport system including various types of transport devices.

Next, a method for the transport control device 130 to integrally control different types of transport devices will be described. In the following description, a method for the transport control device 130 to integrally control the plurality of first transport devices 110a, 110b, . . . , 110n and the plurality of second transport devices 120a, 120b, . . . , 120n will be described. However, the above method is only an example, and in this embodiment, based on the method, not only two transport devices of different types (i.e., a plurality of first transporting devices 110a, 110b, . . . , 110n and the plurality of second transport devices 120a, 120b, . . . , 120n), but also three or more transport devices of different types (e.g., the plurality of first transport devices 110, the plurality of second transport devices 120, . . . , a plurality of nth transport devices 150) can also be integrally controlled.

In this embodiment, transport can be performed by dynamically assigning various types of transport means in one control system. The transport control device 130 is for this purpose and can integrally control the plurality of first transport devices 110a, 110b, . . . , 110n and the plurality of second transport devices 120a, 120b, . . . , 120n. The transport control device 130 may be provided as a dynamic transport controller that dynamically assigns and controls different types of transport means.

If congestion occurs on a path in progress or a path that is more optimized than the existing path exist after the first means is assigned for one transport, the transport control device 130 may assign the transport to a different type of transport means and transports the transported object to shorten the transport time and increase the transport efficiency of the entire line. For example, if congestion occurs on the OHT's moving path while transporting the transported object to the destination using the OHT, the transported object can be transported to the destination using the AGV.

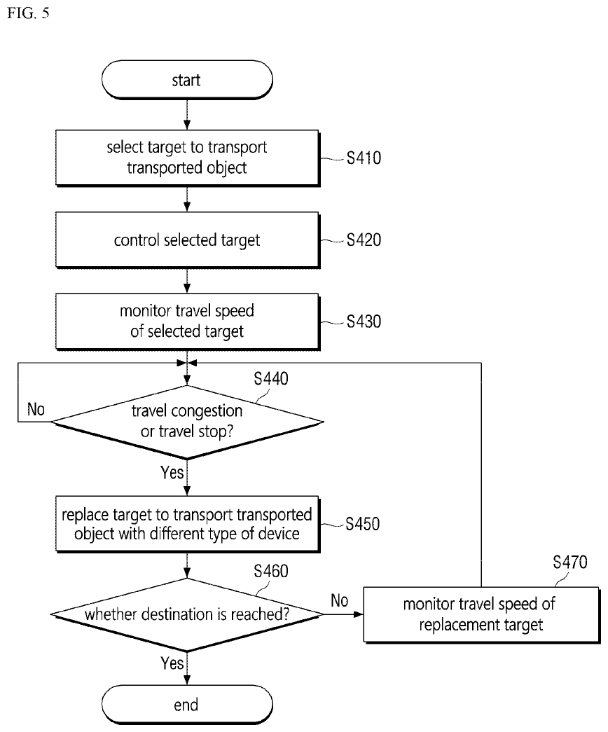

FIG. 5 is an exemplary diagram for describing a method for a transport control device constituting a logistics transport system to control different types of transport devices.

First, the transport control device 130 selects a target to transport a transported object from among the plurality of first transport devices 110a, 110b, . . . , 110n and the plurality of second transport devices 120a, 120b, . . . , 120n (S410).

The transport control device 130 may select a transport device having the shortest moving distance as the target to transport the transported object. Here, the shortest moving distance means that the sum of the moving distance from the current position to the place where the transported object is located and the moving distance from the position of gripping the transported object to the destination is the shortest.

The transport control device 130 may select a transport device having the shortest moving time as the target to transport the transported object. Here, the shortest moving time means that the sum of the moving time from the current position to the place where the transported object is located and the moving time from the position of gripping the transported object to the destination is the shortest. The moving time may be a value in consideration of transport delay due to traffic congestion in the corresponding section. The value considering the transport delay may follow a statistical value calculated according to traffic volume per hour and section in normal times.

The transport control device 130 may select a transport device in an idle state as the target to transport the transported object. The transport control device 130 may arbitrarily select any one of the plurality of transport devices in an idle state, and may also select one of them in consideration of a moving distance or a moving time.

When a target to transport the transported object is selected, the transport control device 130 controls the transport device so that the transport of the transported object can proceed smoothly (S420). Hereinafter, it is assumed that the 1A transport device 110a, which is any one of the plurality of first transport devices 110a, 110b, . . . , 110n, is selected as the target to transport the transported object.

The transport control device 130 monitors the travel speed of the 1A transport device 110a while the 1A transport device 110a is transporting the transported object (S430). The transport control device 130 may monitor the travel speed of the 1A transport device 110a using a plurality of sensors installed around the moving path of the 1A transport device 110a, and also may monitor the travel speed of the 1A transport device 110a using the speedometer mounted on the 1A transport device 110a. The transport control device 130 may monitor the travel speed of the 1A transport device 110a to determine whether an obstacle to the 1A transport device 110 such as travel congestion or travel stop has occurred (S440).

As a result of the monitoring, when it is determined that travel congestion or travel stop has occurred to the 1A transport device 110a, the transport control device 130 selects again a target to transport the transported object in replace with the 1 A transport device 110a from among the plurality of second transport devices 120a, 120b, . . . , 120n (S450).

The transport control device 130 may select a transport device having the shortest moving distance as the target to transport the transported object. Here, the shortest moving distance means that the sum of the moving distance from the current position to the place where the 1A transport device 110a is located and the moving distance from the position where the transported object is delivered to the destination is the shortest.

The transport control device 130 may select the transport device having the shortest moving time as the target to transport the transported object. Here, the shortest moving time means that the sum of the moving time from the current position to the place where the 1A transport device 110a is located and the moving time from the position where the transported object is delivered to the destination is the shortest. The moving time may be a value in consideration of transport delay due to traffic congestion in the corresponding section. The value considering the transport delay may follow a statistical value calculated according to traffic volume per hour and section in normal times.

The transport control device 130 may select a transport device in an idle state as the target to transport the transported object. The transport control device 130 may arbitrarily select any one of the plurality of transport devices in an idle state, and may also select one of them in consideration of a moving distance or a moving time.

When the target to transport the transported object is changed to another type of transport device according to such re-selection, the transport control device 130 monitors the corresponding type of the transport device, and the transport control device 130 repeatedly performs monitoring of the traveling speed (S470) and replacement of the transport target according to the monitoring result (S440, S450) until the transported object reaches the destination (S460) in order to minimize the delay in transporting the transported object.

On the other hand, the transport control device 130 does not monitor the 1A transport device 110a, but the 1A transport device 110a can determine whether a failure of travel congestion or travel stop occurs to the 1A transport device 110a based on the information provided by the 1A transport device 110a. In this case, the 1A transport device 110a may provide the transport control device 130 with its own speed information, information obtained by capturing the surroundings, and the like.

On the other hand, among the plurality of first transport devices 110a, 110b, . . . , 110n, if the transport devices selected from the rest 110b, . . . , 110n except for the 1A transport device 110a is determined to more quickly transport the transported object than the plurality of second transport devices 120a, 120b, . . . , 120n, it is also possible to select the target to transport the transported object from the rest 110b, . . . , 110n.

As described above, the transport control device 130 may integrally control different types of transport means. The transfer control device 130 may be provided as a vehicle control system (VCS) for this purpose.

Several types of transport means can be utilized on one line depending on the transport position. Each transport means requires a separate protocol and control suitable for each characteristic, and for this purpose, classification of transport means is required in the control system. In this embodiment, each transport means is classified in one control system, and an optimal path is searched for based on this, and the corresponding transport means can be controlled and transported.

The transport control device 130 may dynamically assign different types of transport means. If one task is assigned to only a specific transport means, transport delays may occur due to the following reasons.

First, if a failure occurs in the corresponding path after the initial path assignment, but the detour path is very unreasonable, a transport delay may occur.

Second, if a failure occurs in the only path and transport is impossible until the failure is resolved, a transport delay may occur.

Third, if the path itself is unreasonable due to the existence of obstacles in the path of the transport means, a transport delay may occur.

Conventional control systems cannot cope with such irrationality, so real (path) changes such as rail remodeling are required to solve this problem, which may require a lot of man-hours and costs. In this embodiment, it is possible to search, assign, and control a path so that one transport can be carried out across multiple transport means. In this embodiment, through this, it is possible to appropriately respond to transport delays in various cases.

First, if there is no detour path of the existing transport means or it is very unreasonable, it is possible to proceed with the transportation through other transport means.

Second, if obstacles in a specific region can be avoided by other transport means, the transport can be carried out through the corresponding transport means.

In order to search for an optimal path, the transport control device 130 searches for a path across several transport means, rather than a path limited to a specific transport means. In this embodiment, the transport can always proceed through the optimal path through the path searched in this way regardless of the path state of the transport means initially assigned.

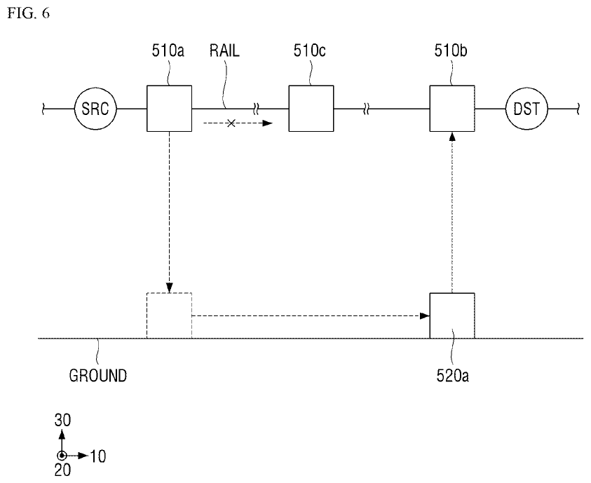

The transport control device 130 may transport the transported object to the destination by avoiding an unmovable section by dynamically assigning different types of transport means. Referring to the example of FIG. 6, when the first OHT 510a is selected as a target to transport a transported object, in order to transport the transported object to the destination DST, it can move from the starting point SRC to the destination DST along the moving path of the transported object set on the rail. However, when the third OHT 510c stops traveling due to an error on the moving path of the first OHT 510a, the first OHT 510a cannot move along the rail to the destination DST, and it becomes impossible to transport the transported object to the destination DST.

Therefore, in this case, the transported object can be transported to the vicinity of the destination DST using the first AGV 520a, which can avoid congestion since it moves on the ground. In other words, it is possible to continue transporting by a new path through another transport means.

When the first AGV 520a arrives near the destination DST, the waiting second OHT 510b receives the transported object from the first AGV 520a and can finally transport the transported object to the destination DST.

In this embodiment, it is possible to return to the existing transport means as described above to complete the transportation, but the present embodiment is not necessarily limited thereto, and it is also possible that the first AGV 520a directly carries the transported object to the destination DST, or the transported object is transported to the destination DST using the tower lifter. FIG. 6 is a first exemplary diagram for describing dynamic assignment and integrated control of a transport control device constituting a logistics transport system.

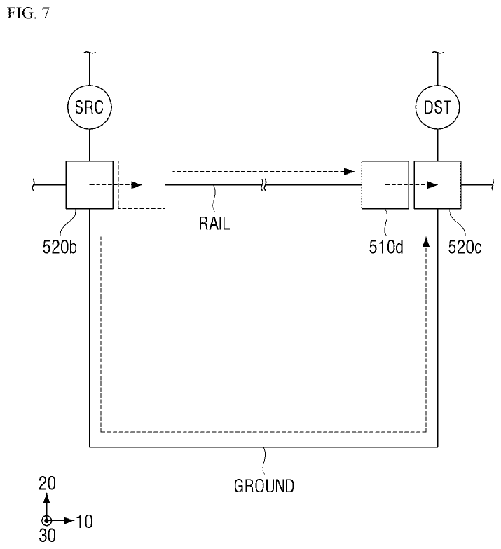

The transport control device 130 may transport the transported object to the destination by shortening the moving section by dynamically assigning different types of transport means. Referring to the example of FIG. 7, when the second AGV 520b is selected as a target to transport a transported object, it can move from the starting point SRC to the destination DST along the moving path of the transported object set on the ground to transport the transported object. However, due to various obstacles (e.g., other AGVs, process facilities, etc.) located on the ground, the moving path of the transported object may be very long.

Therefore, in this case, it is possible to transport the transported object to the vicinity of the destination DST by moving the shortened section with the fourth OHT 510d. In other words, it is possible to continue transporting by a new path through another transport means.

When the fourth OHT 510d arrives near the destination DST, the waiting third AGV 520c receives the transported object from the fourth OHT 510d and can finally transport the transported object to the destination DST.

In this embodiment, it is possible to return to the existing transport means as described above to complete the transportation, but as described above, the present embodiment is not necessarily limited thereto. FIG. 7 is a second exemplary diagram for describing dynamic assignment and integrated control of a transport control device constituting a logistics transport system.

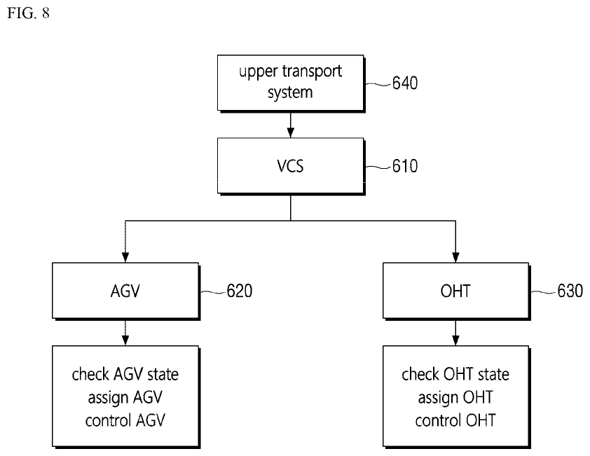

As described above, the transport control device 130 may dynamically assign and integrally control different types of transport means. Therefore, as shown in FIG. 8, since simultaneous control of various types of transport means such as AGV 620 and OHT 630 is possible in one control system (VCS) 610, the upper transport system 640 can give the transport to the control system 610 regardless of type of the transported object or transport position. In addition, since the upper transport system 640 simply generates transport and the control system 610 searches for the optimal transport means, it is possible to immediately respond to the situation at the transport site. FIG. 8 is a third exemplary diagram for describing dynamic assignment and integrated control of a transport control device constituting a logistics transport system.

In addition, in the present embodiment, an optimal path may be searched by periodically calculating paths for various transport means through the transport control device 130 not only at the time of transport generation but also during transport. In this embodiment, a path with higher efficiency can be searched through this, and thus an effect of improving transport efficiency can be obtained.

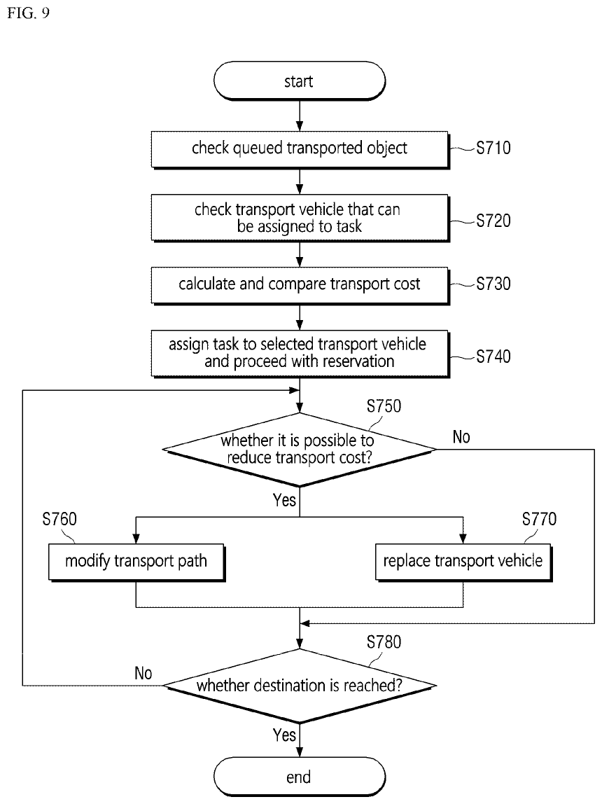

Hereinafter, path search and task assignment for each transport means will be described. FIG. 9 is a first exemplary diagram for describing path search and task assignment for each transport means of the transport control device constituting the logistics transport system.

First, the transport control device 130 checks transported objects waiting for transport (S710).

If there is a transported object waiting for transport, the transport control device 130 checks transport vehicles that can be assigned task, such as OHT and AGV (or AMR) (S720).

When there are a plurality of transport vehicles, to which task can be assigned, the transport control device 130 calculates a transport cost for each transport vehicle and compares the transport cost of each transport vehicle (S730). The transport cost may be calculated based on, for example, a moving distance, a moving time, idleness, and the like.

When a transport vehicle having the lowest transport cost is extracted according to the comparison result (S730), the transport control device 130 assigns a task to the transport vehicle and controls the transport vehicle to transport the transported object (S740).

The transport control device 130 may determine in real time whether it is possible to reduce the cost of transporting the transported object from the current position to the destination even while the transport vehicle assigned the task is transporting the transported object (S750). Here, if it is determined that it is possible to reduce the transport cost, the transport control device 130 modifies the transport path (S760) or replaces the transport vehicle (S770) and controls the transported object to be transported, and the above determination and control (S750, S760, S770) may be continuously repeated until the transported object reaches the destination (S780).

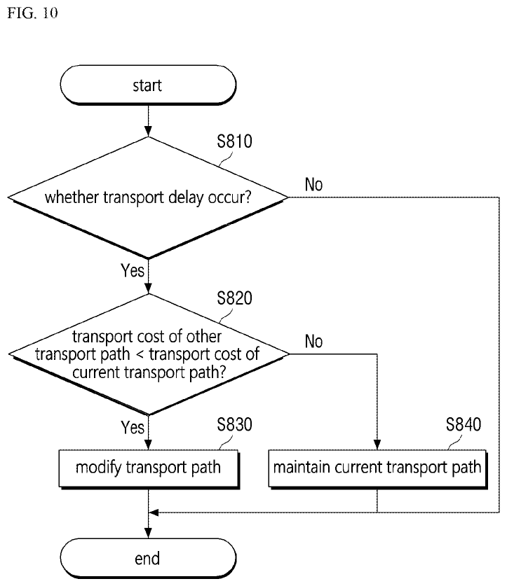

In the above, the process of determining whether it is possible to reduce the transport cost may be specifically executed as follows. FIG. 10 is a second exemplary diagram for describing path search and task assignment for each transport means of the transport control device constituting the logistics transport system.

First, the transport control device 130 checks whether a transport delay, such as traffic congestion or stoppage, has occurred to the transport vehicle transporting the transported object (S810).

If it is confirmed that the transport delay has occurred, the transport control device 130 calculates the transport cost for each of the current transport path and other transport paths, and compares them with each other (S820).

If it is determined that another transport path has a lower transport cost than the current transport path according to the comparison result (S820), the transport control device 130 modifies the transport path (S830).

On the other hand, if the current transport path is determined to have a lower transport cost than other transport paths according to the comparison result or if the transport cost between the current transport path and other transport paths is determined to be the same (S820), the transport control device 130 maintains the current transport path (S840).

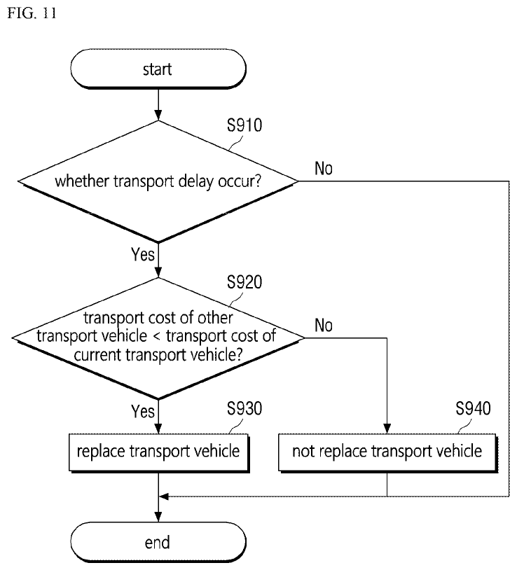

On the other hand, it is also possible that the process of determining whether it is possible to reduce the transport cost is executed as follows. FIG. 11 is a third exemplary diagram for describing path search and task assignment for each transport means of the transport control device constituting the logistics transport system.

First, the transport control device 130 checks whether a transport delay, such as congestion or stoppage, has occurred to the transport vehicle transporting the transported object (S910).

If it is confirmed that the transport delay has occurred, the transport control device 130 calculates transport costs for each of the current transport vehicle and other transport vehicles, and compares them with each other (S920).

If it is determined that other transport vehicle has a lower transport cost than the current transport vehicle according to the comparison result (S920), the transport control device 130 replaces the transport vehicle (S930).

On the other hand, if the current transport vehicle is determined to have a lower transport cost than other transport vehicle according to the comparison result or if the transport cost between the current transport vehicle and other transport vehicles is determined to be the same (S920), the transport control device 130 maintains the transport vehicle as it is without replacing it (S940).

The method for determining whether it is possible to reduce the transport cost has been described with reference to FIGS. 10 and 11 above. The transport control device 130 may determine whether it is possible to reduce the transport cost by using at least one of the method described with reference to FIG. 10 and the method described with reference to FIG. 11. For example, when a transported object is transported using OHT, the transport control device 130 may determine whether it is possible to reduce transport costs by the method described with reference to FIG. 10 if there is no AGV in an idle state. In addition, the transport control device 130 determines whether it is possible to reduce the transport cost by the method described with reference to FIG. 11, and when the transport vehicle is not replaced, it is also possible to re-determine whether it is possible to reduce the transport cost by the method described with reference to FIG. 10.

On the other hand, in the present embodiment, when transport congestion and errors occur, the use of the buffer can be minimized by continuing the transport through different types of transport means, rather than storing in a specific buffer. In this embodiment, it is possible to obtain an effect of improving space efficiency through this. For example, when a rail is congested during transport through OHT, the transport can proceed regardless of the rail situation by assigning the transport to an AGV or AMR and moving the transported object.

The transport control device 130 for integrating and controlling different types of transport means and the logistics transport system 110 including the same have been described above with reference to FIGS. 1 to 11. According to the present disclosure, it is possible to shorten the transport time by searching for, assigning, and controlling a path so that each transport means is distinguished and controlled in one control system, and one transport can proceed across several means based on this. In addition, it is expected that space efficiency can be improved by minimizing the use of a buffer by proceeding with the transportation through new transport means in case of transport congestion or error.

Although the embodiments of the present disclosure have been described with reference to the accompanying drawings, the present disclosure is not limited to the above embodiments and can be manufactured in a variety of different forms, and those skilled in the art in the art to which the present disclosure belongs will understand that the present disclosure may be embodied in other specific forms without changing the technical concept or features. Therefore, the embodiments described above should be understood as illustrative in all respects and not limiting.

What is claimed is:

1. A logistics transport system comprising:
a plurality of first transport devices disposed in a semiconductor manufacturing plant and for transporting a transported object;
a plurality of second transport devices different in type from the plurality of first transport devices; and
a transport control device for controlling the plurality of first transport devices and the plurality of second transport devices,
wherein the transport control device integrates and operates different types of transport devices to transport the transported object.

2. The system of claim 1, wherein the transport control device transports the transported object using any one of the first transport device and the second transport device, and transports the transported object using another one when a failure occurs.

3. The system of claim 1, wherein the transport control device dynamically assigns transport of the transported object to the different types of transport devices.

4. The system of claim 1, wherein the transport control device avoids an unmovable section or shortens a moving section by using the different types of transport devices.

5. The system of claim 1, wherein the transport control device searches for an optimal path in real time for a plurality of transport devices including a transport device transporting the transported object while the transported object is being transported.

6. The system of claim 1, wherein the transport control device selects a transport device to transport the transported object based on a transport cost.

7. The system of claim 6, wherein the transport cost is calculated based on at least one of a moving distance, a moving time, and idleness.

8. The system of claim 1, wherein the transport control device monitors in real time whether it is possible to reduce a transport cost in relation to transport of the transported object when a specific transport device transports the transported object.

9. The system of claim 8, wherein the transport control device considers a transport path or a transport target when monitoring whether it is possible to reduce the transport cost.

10. The system of claim 9, wherein the transport control device sequentially considers the transport path and the transport target.

11. The system of claim 1, wherein the transport control device modifies a transport path or replaces a transport device according to a transport cost when a specific transport device transports the transported object.

12. The system of claim 11, wherein the transport control device compares an existing path with a new path and modifies a transport path to the new path if the new path is an optimal path considering the transport cost.

13. The system of claim 11, wherein the transport control device compares the specific transport device with other transport device and replaces the transport device with the other transport device when the other transport device has an optimal path, in which the transport cost is considered.

14. The system of claim 1, wherein the plurality of first transport devices travel on a ceiling of the semiconductor manufacturing plant to transport the transported object,
wherein the plurality of second transport devices travel on a ground of the semiconductor manufacturing plant to transport the transported object.

15. The system of claim 1 further comprises,
a plurality of third transport devices different in type from the plurality of first transport devices and the plurality of second transport devices.

16. A logistics transport system comprising:
a plurality of first transport devices disposed in a semiconductor manufacturing plant and for transporting a transported object;
a plurality of second transport devices different in type from the plurality of first transport devices; and
a transport control device for controlling the plurality of first transport devices and the plurality of second transport devices,
wherein the transport control device transports the transported object by integrating and operating different types of transport devices,
wherein the transport control device dynamically assigns transport of the transported object to the different types of transport devices,
wherein the transport control device avoids an unmovable section or shortens a moving section by using the different types of transport devices,
wherein the transport control device monitors in real time whether it is possible to reduce a transport cost in relation to transport of the transported object when a specific transport device transports the transported object,
wherein the transport control device modifies a transport path or replaces the transport device according to the transport cost when the specific transport device transports the transported object.

17. A transport control device disposed in a semiconductor manufacturing plant,
wherein the transport control device,
controls a plurality of first transport devices for transporting a transported object and a plurality of second transport devices different in type from the plurality of first transport devices,
transports the transported object by integrating and operating different types of transport devices, and
dynamically assigns transport of the transported object to the different type of transport devices.

18. The transport control device of claim 17, wherein the transport control device transports the transported object using any one of the first transport device and the second transport device, and transports the transported object using another one when a failure Occurs.

19. The transport control device of claim 17, wherein the transport control device avoids an unmovable section or shortens a moving section by using the different types of transport devices.

20. The transport control device of claim 17, wherein the transport control device monitors in real time whether it is possible to reduce a transport cost in relation to transport of the transported object when a specific transport device transports the transported object.
